(19) United States
(12) Patent Application Publication
(10) Pub. No.: US 2023/0389432 A1
(43) Pub. Date: Nov. 30, 2023

(54) PIEZOELECTRIC ELEMENT, LIQUID EJECTION HEAD, AND IMAGE RECORDING APPARATUS

(71) Applicant: CANON KABUSHIKI KAISHA, Tokyo (JP)

(72) Inventor: TAKASHI IKEDA, Kanagawa (JP)

(21) Appl. No.: 18/324,082

(22) Filed: May 25, 2023

(30) Foreign Application Priority Data
May 30, 2022 (JP) 2022-087976

(51) Int. Cl. H10N 30/85; B41J 2/14; H10N 30/50; H10N 30/00

(52) U.S. Cl. CPC H10N 30/85; B41J 2/14201; H10N 30/50; H10N 30/1051

(57) ABSTRACT

A piezoelectric element includes a lower electrode, a piezoelectric film, and an upper electrode in this order on a substrate. An aluminum oxide film containing at least one element selected from the group consisting of elements of group III, elements of group IV, and elements of group V, of the periodic table is disposed between the lower electrode and the piezoelectric film.

### BACKGROUND OF THE INVENTION

### Field of the Invention

The present disclosure relates to a piezoelectric element, a liquid ejection head, and an image recording apparatus.

### Description of the Related Art

Piezoelectric members having a shape which is changed due to application of an electric field and serving as devices for infinitesimally and precisely moving or vibrating an object are applied to various industrial products. Piezoelectric members are used for, for example, small speakers, hard disk drives, and printers (image recording apparatuses).

Of these, some printers adopt a piezoelectric film for a liquid ejection head for ejecting a liquid droplet. Regarding such a liquid ejection head, a piezoelectric film is driven due to application of an electric field by electrodes (upper electrode and lower electrode) formed vertically holding the piezoelectric film so as to eject a liquid droplet.

In recent years, printers have been required to have high-definition image quality and high-speed performance, and the ejection structure of a liquid ejection head has been miniaturized and devised so that a piezoelectric film is largely displaced due to application of high voltage. On the other hand, application of high voltage generates a high load in the piezoelectric film. That is, although the piezoelectric film is a type of insulator, the specific resistance (electrical resistivity) is low compared with silicon oxide or the like, and a slight current may pass through the film due to application of high voltage. An occurrence of dielectric breakdown due to the current has an influence on the durability of the piezoelectric film.

Therefore, research on an improvement of the durability of the piezoelectric film has been performed. For example, Japanese Patent No. 4736021 describes a technology to suppress a current from passing through a piezoelectric film so as to improve the durability by forming an insulating film between the piezoelectric film and an electrode.

The technology disclosed in Japanese Patent No. 4736021 may improve the durability of the piezoelectric film. However, a technical disadvantage occurs in that a sufficient amount of displacement of the piezoelectric film is not obtained. It is conjectured that the cause of this is due to the magnitude of the electric field applied to the piezoelectric film being decreased by the voltage applied by the electrode being distributed to the insulating film and the piezoelectric film. In this regard, there is a method in which the voltage applied to the electrode is increased in consideration of a decrease in the electric field applied to the piezoelectric film. In such an instance, deterioration of other portions such as wiring lines may occur. As another method, a method in which the distribution rate of the voltage to the piezoelectric film was increased by decreasing the film thickness of the insulating film was attempted. However, a high electric field was still applied to the insulating film.

### SUMMARY OF THE INVENTION

The present disclosure was realized in consideration of the above-described disadvantages and provides a piezoelectric element capable of sufficiently obtaining the amount of displacement of a piezoelectric film and enhancing the durability of the piezoelectric film.

A piezoelectric element according to the present disclosure includes a lower electrode, a piezoelectric film, and an upper electrode in this order on a substrate, and an aluminum oxide film containing at least one element selected from the group consisting of elements of group III, elements of group IV, and elements of group V, of the periodic table is disposed between the lower electrode and the piezoelectric film.

Further features of the present disclosure will become apparent from the following description of exemplary embodiments with reference to the attached drawings.

### BRIEF DESCRIPTION OF THE DRAWINGS

FIG. 1 is a schematic sectional view illustrating a piezoelectric element according to the present disclosure having a structure in which an insulating film is disposed between a piezoelectric film and a lower electrode.

FIG. 2 is a schematic sectional view illustrating a piezoelectric element according to the present disclosure having a structure in which an insulating film is disposed between a piezoelectric film and an upper electrode.

FIG. 3 is a schematic sectional view illustrating a piezoelectric element according to the present disclosure having a structure in which an insulating film is disposed between a piezoelectric film and a lower electrode and between the piezoelectric film and an upper electrode.

FIG. 4 is a sectional view illustrating a lower electrode including an adhesion layer.

FIG. 5 is a graph illustrating results of a high-temperature high-humidity driving test.

FIG. 6 is a sectional view illustrating a crystal-orientation-oriented film including an adhesion layer.

FIG. 7 is a sectional view illustrating a film configuration of a piezoelectric element according to the present disclosure, where an insulating film is disposed between a piezoelectric film and a lower electrode.

FIG. 8 is a sectional view illustrating a working process of a piezoelectric element according to the present disclosure and illustrating the state in which a resist mask pattern for working a piezoelectric member is formed.

FIG. 9 is a sectional view illustrating the manner of an etched film of a piezoelectric element according to the present disclosure.

FIG. 10 is a sectional view illustrating a film configuration of a piezoelectric element according to the present disclosure, where an insulating film is disposed between a piezoelectric film and an upper electrode.

FIG. 11 is a schematic sectional view illustrating a working process of a piezoelectric element according to the present disclosure and illustrating the state in which a protective film is formed.

FIG. 12 is a sectional view illustrating a working process of a piezoelectric element according to the present disclosure and illustrating a resist mask pattern for forming an opening portion on the lower electrode surface.

FIG. 13 is a sectional view illustrating a working process of a piezoelectric element according to the present disclosure and illustrating the state in which an opening portion is formed on the lower electrode surface.

FIG. 14 is a sectional view illustrating a working process of a piezoelectric element according to the present disclosure and illustrating a resist mask pattern for forming an opening portion on the upper electrode surface.

FIG. 15 is a sectional view illustrating a working process of a piezoelectric element according to the present disclosure and illustrating the state in which an opening portion is formed on the upper electrode surface.

FIG. 16 is a sectional view illustrating a working process of a piezoelectric element according to the present disclosure and illustrating a conductive film formed to form a wiring line.

FIG. 17 is a sectional view illustrating a working process of a piezoelectric element according to the present disclosure and illustrating a resist mask pattern formed for working the conductive film into a predetermined shape so as to serve as a wiring line.

FIG. 18 is a sectional view illustrating a working process of a piezoelectric element according to the present disclosure and illustrating a formed wiring line.

FIG. 19 is a sectional view illustrating a working process of a piezoelectric element according to the present disclosure and illustrating a resist mask pattern for forming a recessed portion in the wafer back surface.

FIG. 20 is a sectional view illustrating a configuration of a SOI wafer.

### DESCRIPTION OF THE EMBODIMENTS

A piezoelectric element serving as a microstructure produced by using a semiconductor process will be described below in detail as an embodiment of the piezoelectric element according to the present disclosure with reference to the attached drawings. In this regard, constituent elements described in the following embodiment are no more than exemplifications, and these are not intended to limit the scope of the present disclosure.

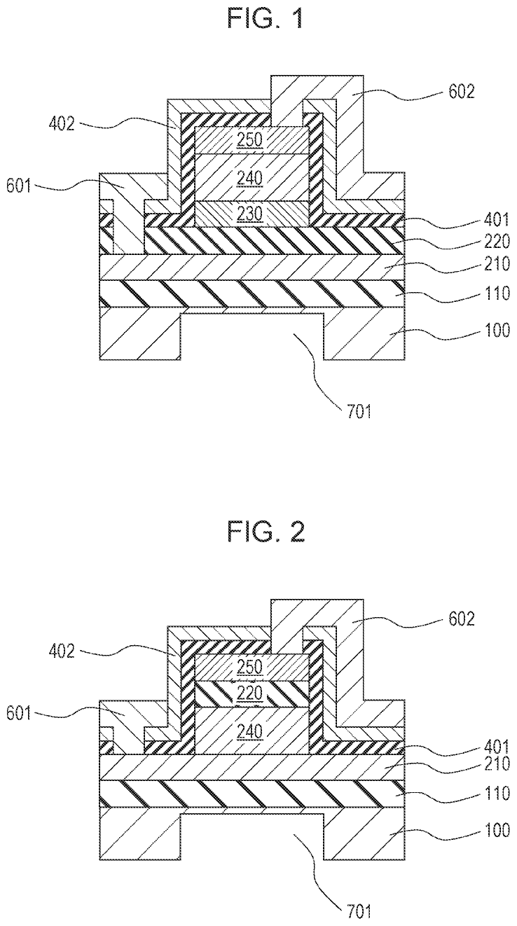

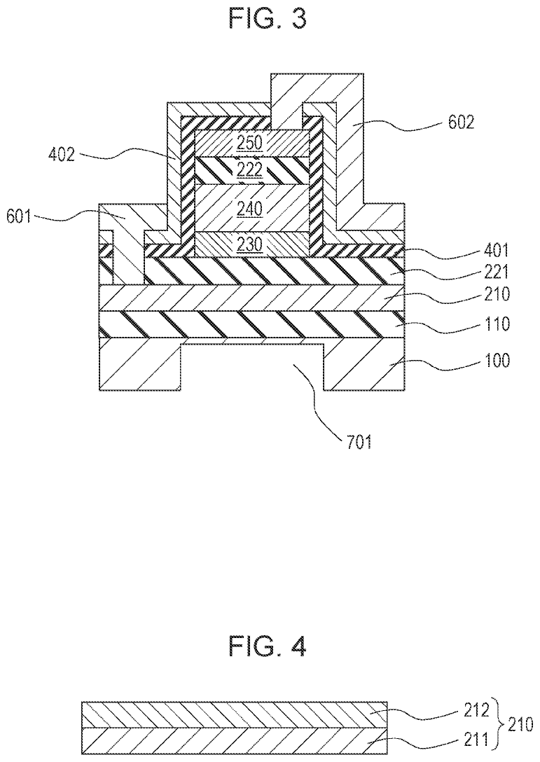

As illustrated in FIG. 1, the piezoelectric element according to the present disclosure includes a lower electrode 210, a piezoelectric film 240, and an upper electrode 250 in this order on a substrate 100 and includes an insulating film 220 between the lower electrode and the piezoelectric film. In such an instance, as described above, the presence of the insulating film 220 suppresses a current from passing through the piezoelectric film. As the reference configuration illustrated in FIG. 2, the insulating film 220 may be disposed between the piezoelectric film 240 and the upper electrode 250, and as illustrated in FIG. 3, the insulating film 220 can be disposed between the lower electrode 210 and the piezoelectric film 240 and between the piezoelectric film 240 and the upper electrode 250.

When the piezoelectric element according to the present disclosure is a microstructure, in particular, the piezoelectric element can be formed on the flat substrate 100. The substrate 100 may be appropriately selected in accordance with the application thereof, and a highly flat wafer composed of a material such as silicon, silicon carbide, quartz, gallium nitride, gallium arsenide, indium phosphide, or sapphire is favorably used. Further, a SOI (Silicon On Insulator) wafer may be used to readily form a membrane structure.

Explanations will be provided below in detail with reference to the piezoelectric element including the insulating film 220 between the piezoelectric film 240 and the lower electrode 210.

The lower electrode 210 of the piezoelectric film 240 may be exposed to high temperature of several hundreds ° C. in a process thereafter, and in such an instance, a material having a high melting temperature can be used. Examples of such a material include copper, platinum, gold, chromium, cobalt, and titanium and alloys thereof. In this regard, when the piezoelectric film 240 is formed in contact with the upper surface of the lower electrode 210, the lower electrode 210 may also serve as a film for controlling the crystal orientation of the piezoelectric film. In such an instance, a material having an appropriate crystal structure is appropriately selected as the material to be used. In addition, the lower electrode 210 may be a multilayer film of a thin film of titanium, chromium, or the like disposed as the adhesion layer 211 to obtain adhesion strength to the film under the lower electrode 210 and the conductive layer 212 composed of the above-described material or a common material used for a wiring line. As described above, when the piezoelectric film 240 is formed in contact with the conductive layer 212, the material having an appropriate crystal structure is appropriately selected for forming the conductive layer 212 (refer to FIG. 4). When the substrate 100 has electrical conductivity, an insulating film 110 can be disposed between the lower electrode 210 and the substrate 100. A common insulator material, for example, silicon oxide, silicon nitride, oxynitride, or alumina, can be used for the insulating film 110.

The insulating film 220 for suppressing a current from passing through the piezoelectric film is formed on the lower electrode 210 or on the piezoelectric film 240 (refer to FIG. 1 to FIG. 3). In the present disclosure, the insulating film has to be an aluminum oxide film containing at least one element selected from the group consisting of elements of group III, elements of group IV, and elements of group V, of the periodic table. Examples of the at least one element selected from the group consisting of elements of group III, elements of group IV, and elements of group V, of the periodic table include titanium, lanthanum yttrium, and hafnium. More specifically, the aluminum oxide can be at least one member selected from the group consisting of aluminum titanate, yttrium aluminate, hafnium aluminate, and lanthanum aluminate. In this regard, the insulating film may be nitrogen-incorporated hafnium aluminate or the like which further contains nitrogen.

A piezoelectric element was produced by using an insulating film of aluminum oxide containing at least one element selected from the group consisting of elements of group III, elements of group IV, and elements of group V, of the periodic table according to the configuration of the present disclosure or by using an insulating film composed of a material used in the related art, and a high-temperature high-humidity driving test was performed. The test condition was as described below. That is, the piezoelectric element was held in a vessel set at a temperature of 85° C. and a relative humidity of 85% RH, and application of a constant voltage was continued for 1,000 hours.

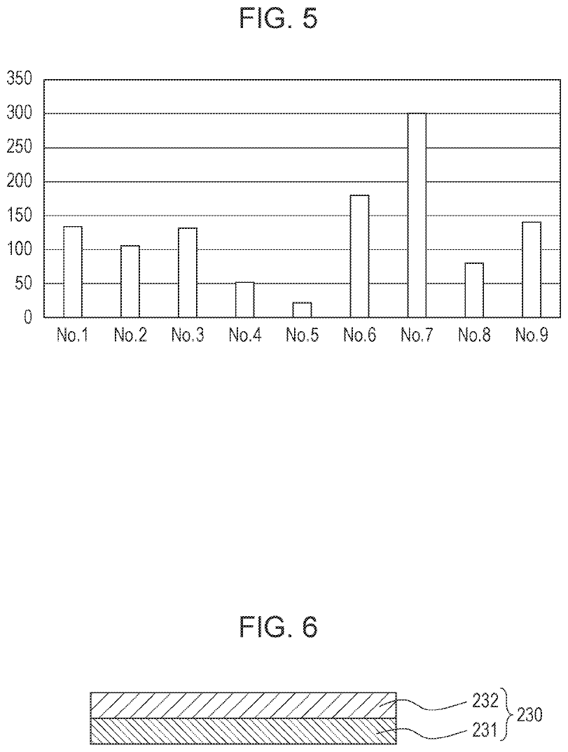

Table and FIG. 5 illustrates the results of the high-temperature high-humidity driving test. Table represents the material for forming the insulating film used for the test, the relative permittivity, the dielectric breakdown electric field strength, and the product of the relative permittivity and the dielectric breakdown electric field strength of each film. FIG. 5 is a diagram illustrating the graph of the product of the relative permittivity and the dielectric breakdown electric field strength. In this regard, in Table, the piezoelectric element that exhibited high durability is marked with “o”. According to the results of the test, a material having a higher product of the relative permittivity and the dielectric breakdown electric field strength exhibited higher durability. In particular, it was found that the durability increases when the product of the relative permittivity and the dielectric breakdown electric field strength is more than 134 MV/cm. This is also clear from a comparison between the instance in which alumina having the above-described product of 134 MV/cm was used and the instance in which hafnium aluminate having the product slightly larger than 134 MV/cm was used.

TABLE

| | | Dielectric | | | |
|---|---|---|---|---|---|
| | | breakdown | | Product of relative | |
| | | electric field | | permittivity and | |
| | | strength | Relative | dielectric breakdown | |
| | | A | permittivity | electric field strength | Evaluation |
| No. | Material | [MV/cm] | B | (A × B) | of durability |
| 1 | Alumina | 13.4 | 10 | 134 | |
| 2 | Silicon | 8.8 | 12 | 105.6 | |
| | nitride | | | | |
| 3 | Silicon | 9.4 | 14 | 131.6 | |
| | oxynitride | | | | |
| 4 | Silicon oxide | 13 | 4 | 52 | |
| 5 | Tantalum | 1 | 22 | 22 | |
| | pentoxide | | | | |
| 6 | Aluminum | 10 | 18 | 180 | ∘ |
| | titanate | | | | |
| 7 | Lanthanum | 16.7 | 18 | 300.6 | ∘ |
| | aluminate | | | | |
| 8 | Spinel | 4 | 20 | 80 | |
| 9 | Hafnium | 11.7 | 12 | 140.4 | ∘ |
| | aluminate | | | | |

In this regard, the film thickness of the insulating film was adjusted to a thickness so that a predetermined amount of displacement was obtained at a power supply voltage of 50 V. Among the materials, the material capable of having the largest thickness was aluminum titanate and lanthanum aluminate, and the thickness thereof was 13 nm. That is, the film thickness of the insulating film can be 13 nm or less.

The insulating film 220 may be favorably a thin film of several nm in accordance with the material thereof. In such an instance, the film can be formed on a flatter surface and can be formed before the piezoelectric film 240. Examples of such a material include hafnium aluminate. In this regard, when the film formation condition is appropriately adjusted and the piezoelectric film 240 is able to be covered, the insulating film may be in the form of being divided into the insulating film 221 and the insulating film 222 and may be formed both on and under the piezoelectric film. In such an instance, the total film thickness of the two films is set to be 13 nm or less.

When the insulating film 220 is formed between the lower electrode 210 and the piezoelectric film 240, a crystal orientation control film 230 for controlling the crystal orientation of the piezoelectric film is formed between the insulating film 220 and the piezoelectric film 240. The material for forming the crystal orientation control film 230 is in accordance with the crystal orientation of the piezoelectric film 240 and is appropriately selected in accordance with the material for forming the piezoelectric film 240. For example, when the material for forming the piezoelectric film 240 is lead zirconate titanate, platinum can be used for the crystal orientation control film 230. A common film formation method such as magnetron sputtering may be used for forming a platinum film, and the film thickness is appropriately adjusted so as to obtain predetermined orientation. To improve the adhesiveness between the platinum and the insulating film 220, the crystal orientation control film 230 may be a multilayer film of the adhesion layer 231 composed of titanium, chromium, or the like and the crystal orientation control layer 232 (refer to FIG. 6).

The piezoelectric film 240 is formed on the crystal orientation control film 230. Lead zirconate titanate that readily obtains a large displacement is mainly used for the piezoelectric film, but other piezoelectric materials, such as barium titanate, lead titanate, lead metaniobate, bismuth titanate, zinc oxide, aluminum nitride, and potassium sodium niobate, may be used.

Regarding film formation of the piezoelectric film 240, a common film formation method such as coating by magnetron sputtering or spin coating may be used. The film thickness can be about 2 μm, and when a film is formed by coating, the film is composed of some layers formed separately. In addition, the crystal orientation is oriented due to firing after coating. The firing temperature is appropriately selected in accordance with the material, and when lead zirconate titanate is used, the firing temperature may be within the range of 600° C. to 900° C.

When the insulating film 220 for suppressing a current from passing through the piezoelectric film 240 is formed between the piezoelectric film 240 and the upper electrode 250, the insulating film 220 is formed in contact with the upper surface of the piezoelectric film 240.

The material to be used and the forming method are akin to those in formation of the insulating film 220 between the lower electrode 210 and the piezoelectric film 240. In this regard, when the film thickness of the insulating film 220 is set to be small and several nm, the coatability thereof may be insufficient due to irregularities of the upper surface of the piezoelectric film 240. In such an instance, the insulating film 220 can be formed between the lower electrode 210 and the piezoelectric film 240.

When the insulating film 220 is not formed between the upper electrode 250 and the piezoelectric film 240, the upper electrode 250 is formed in contact with the upper surface of the piezoelectric film 240. It is sufficient that the upper electrode 250 has electrical conductivity and a material commonly used as an electrode material may be used as the material for forming the upper electrode 250. In this regard, when the piezoelectric film 240 is bent due to large internal stress of the crystal orientation control film 230 and the like, it is also possible to provide reverse internal stress to the upper electrode 250 so as to have a function of cancelling the stress of the whole element.

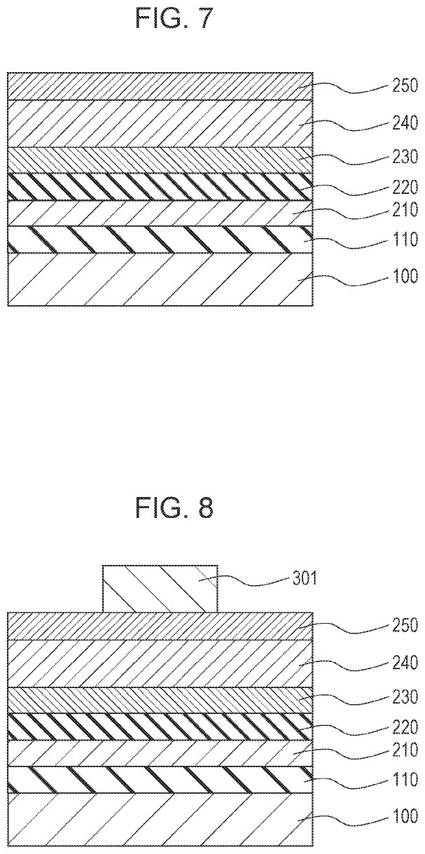

The multilayer film produced as described above (refer to FIG. 7) is worked so as to form a fine piezoelectric element.

A resist pattern 301 having a predetermined shape is formed on the multilayer surface (refer to FIG. 8). A common formation method may be used for forming the resist pattern. That is, a resist is applied by spin coating, pre-bake is performed, ultraviolet rays are applied through a mask provided with a pattern having a predetermined shape, and development is performed so as to remove an unnecessary resist portion. Thereafter, post-bake is performed so as to stabilize the resulting resist pattern and to suppress gas from being released during etching.

Etching is performed by using the produced resist pattern 301 as a mask. A common etching method, such as dry etching or wet etching, may be used for the etching.

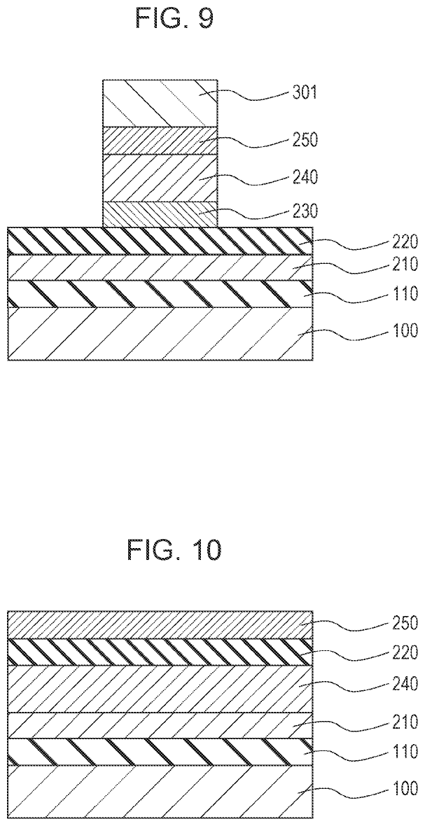

As illustrated in FIG. 9, etching is performed up to the upper surface of the insulating film 220. When the insulating film 220 is not disposed under the piezoelectric film 240, as the film configuration illustrated in FIG. 10, the etching is performed up to the upper surface of the lower electrode 210. After the etching, the resist pattern 301 is removed by a commonly used method, such as ashing.

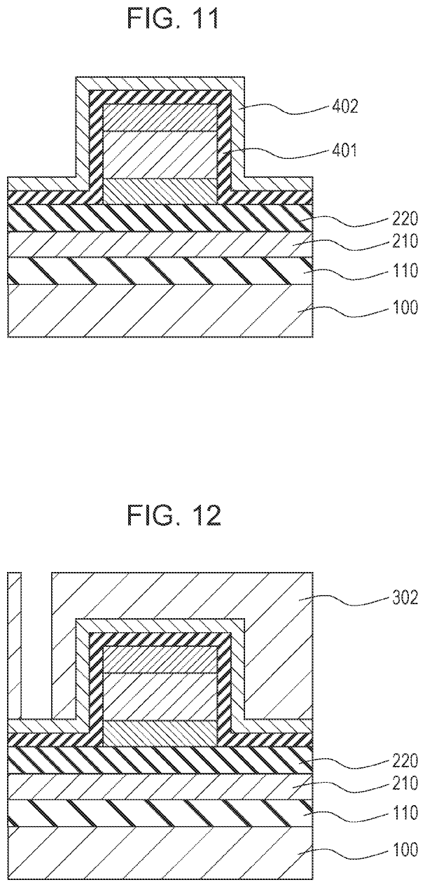

To prevent corrosion of the piezoelectric element that is a microstructure obtained by etching, a protective film 401 is formed on the entire surface of the structure. A common insulating material may be used for the protective film 401. To prevent dielectric breakdown of the protective film 401 at the end portion of the insulating film 220 from occurring, the material akin to the insulating film 220 can be used. To form the protective film 401 on the entire surface of the structure, an atomic layer deposition method or a chemical vapor deposition method can be used. A protective film 402 composed of another material can be formed on the surface of the protective film 401 so as to further improve the protection performance (refer to FIG. 11).

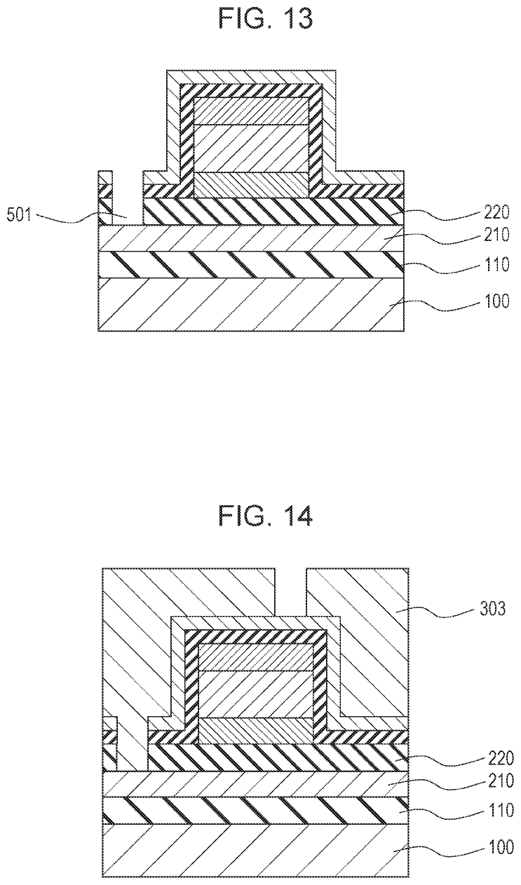

A portion of the above-described protective film is removed, and an opening portion 501 for bringing the lower electrode 210 into contact with a wiring line 601 for electrically coupling an external power supply and the element is formed. A resist pattern 302 having a hole at a place serving as an opening portion is formed (refer to FIG. 12). Thereafter, the protective film 401 or the protective film 401 and the protective film 402 covering the lower electrode 210 are removed by etching. Subsequently, the resist pattern 302 is removed (refer to FIG. 13).

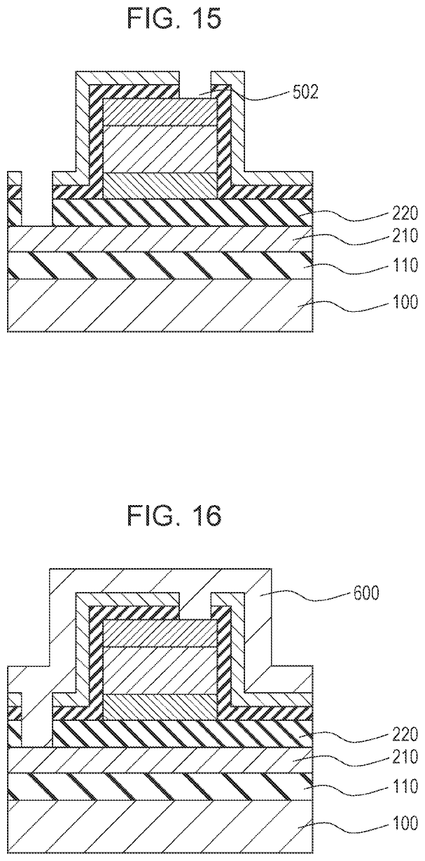

Next, an opening portion 502 for bringing the upper electrode 250 into contact with a wiring line 602 for electrically coupling the external power supply and the element is formed. A resist pattern 303 having a hole at a place serving as an opening portion is formed (refer to FIG. 14). Thereafter, the protective film 401 or the protective film 401 and the protective film 402 covering the upper electrode 250 are removed by etching. Subsequently, the resist pattern 303 is removed (refer to FIG. 15).

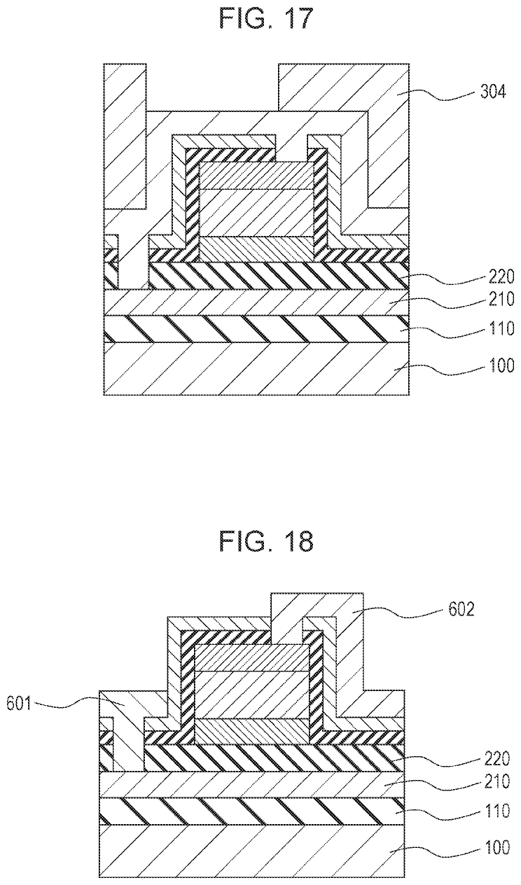

To form the wiring line 601 and the wiring line 602, a conductive film 600 is formed of a conductive material (refer to FIG. 16). Regarding the material, a common wiring line material may be used. Examples of such a material include aluminum, copper, gold, and platinum and alloys thereof. To work the conductive film into a predetermined shape, a resist pattern 304 is formed thereon (refer to FIG. 17). Etching is performed so as to produce the wiring line 601 and the wiring line 602 (refer to FIG. 18).

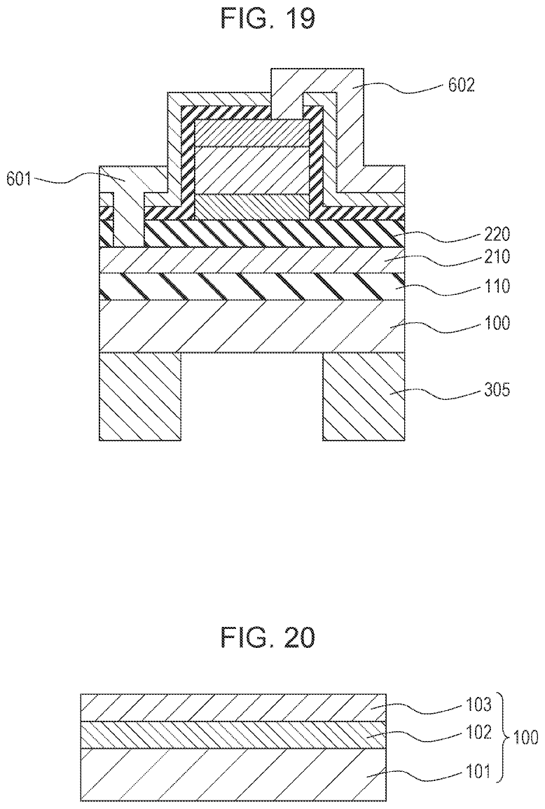

Finally, the back surface of the wafer is thinned so that the piezoelectric element is capable of being deformed due to application of the voltage. The place to be thinned is the back surface of the wafer in the area in which the piezoelectric element produced as above. That is, a thick base body under the piezoelectric element is deeply carved. The working may be machining or a common working method used in a semiconductor process, for example, wet etching, dry etching, or the like. However, since a portion under the piezoelectric element is thinned, it is necessary to pay attention to vibration and the like and not to break a membrane. When working is performed by wet etching or dry etching, a resist pattern 305 illustrated in FIG. 19 is formed. This is used as a mask, and etching is performed so as to form a recessed portion 701 in the back surface of the wafer. The depth of the recessed portion is controlled in accordance with the working time. When a SOI wafer is used as the wafer, it is possible to perform etching with favorable reproducibility of the working depth. FIG. 20 illustrates the structure of the SOI wafer. Regarding the SOI wafer, a silicon oxide layer (BOX layer) is formed on a silicon substrate, and a silicon layer is further present thereon. The BOX layer is formed between several tens of nm and several hundreds of μm, and the film thickness of the silicon layer on the BOX layer may be relatively freely selected. It is possible to remove only silicon by performing selective etching, where the respective thickness of the layers are appropriately combined and the BOX layer serves as an etching stop layer. The bottom section of the recessed portion obtained by such etching is the surface of the BOX layer, and a very flat bottom section is obtained.

The durability of a liquid ejection head is in accordance with, to a great extent, a portion which gives energy for ejection to a liquid, and a liquid ejection head having high durability is obtained by using the above-described piezoelectric element for the liquid ejection head. In addition, compatibility between the high-definition image quality and the high-speed performance is ensured by using an image recording apparatus equipped with the liquid ejection head which ejects a liquid due to the piezoelectric element according to the present disclosure being driven.

### EXAMPLE

A thermal oxidation furnace was used, and a thermally oxidized film was formed on a silicon layer surface by heating a SOI wafer in an oxygen atmosphere. The thickness of the resulting silicon oxide film was 250 nm. The thermally oxidized film interrupts the continuity between an electric circuit formed on the wafer surface and the silicon layer.

Layers of titanium and platinum were successively formed on the thermally oxidized film surface by magnetron sputtering. The film thickness of the titanium layer was set to be 10 nm, and the film thickness of the platinum layer was set to be 20 nm. The resulting conductive multilayer film served as a lower electrode of a piezoelectric film.

Trimethylalminum and tetrakis(dimethylamino)titanium were used as raw materials, and an aluminum titanate insulating film was formed on the lower electrode film surface by an atomic layer deposition method. In such an instance, the wafer temperature was set to be 190° C., and the composition of the titanium element and the aluminum element was set to be 2:3. The film thickness was 8 nm, the relative permittivity was 18, and the dielectric breakdown electric field strength was 10 MV/cm. That is, the product of the relative permittivity and the dielectric breakdown electric field strength was 180 MV/cm. The present insulating film could be formed on a flat film surface since the film thickness was relatively small and, therefore, was formed between the piezoelectric film and the lower electrode.

A layer for controlling the crystal orientation of the piezoelectric film was formed on the aluminum titanate insulating film surface. Regarding this layer, initially, a titanium film serving as an adhesion layer and a platinum film serving as a crystal orientation control layer were successively formed. The film thickness of the titanium film was set to be 10 nm, and the film thickness of the platinum film was set to be 100 nm. Further, a lead titanate solution was applied thereto by spin coating so as to serve as a seed layer.

A lead zirconate titanate sol-gel liquid was applied by using a spin coater to form the piezoelectric film. A thin film having a film thickness of about 200 nm was formed through a single coating step. This was repeated 10 times so that the total thickness was set to be about 2 μm. The piezoelectric film was formed at a firing temperature of 700° C.

After the wafer was slowly cooled, a titanium-tungsten alloy film having a film thickness of 100 nm was formed. The resulting multilayer film served as the upper electrode of the piezoelectric film.

A resist pattern having a size of 600 μm×100 μm was formed on the surface of the thus formed multilayer film, and dry etching was performed up to the depth of the aluminum titanate insulating film surface so as to form a fine piezoelectric element. Further, a resist pattern was formed covering a region slightly broader than the piezoelectric film subjected to etching, and a region apart from the piezoelectric element was dry-etched up to the portion under the lower electrode so as to form the lower electrode slightly extended out of the piezoelectric element.

The entire surface of the piezoelectric element produced by an atomic layer deposition method using trimethylaluminum as a raw material was covered with aluminum oxide. Further, 250 nm of silicon nitride film was formed so as to serve as a protective film for preventing corrosion. To form a contact portion for connecting the upper electrode of the piezoelectric film to a wiring line, the silicon nitride film and the aluminum oxide film on the upper electrode were partly removed by dry etching. Subsequently, to form a contact portion for connecting the lower electrode to a wiring line, the silicon nitride film, the aluminum oxide film, and further the aluminum titanate insulating film were partly removed.

A wiring line for connecting the external power supply circuit to the upper electrode of the piezoelectric element and a wiring line for connecting the external power supply circuit to the lower electrode were formed. A titanium film and an aluminum-copper alloy film were successively formed by using a magnetron sputtering apparatus. The film thickness of the titanium film was set to be 10 nm, and the film thickness of the aluminum-copper alloy film was set to be 30 nm. Thereafter, a resist pattern having the shape of the wiring line was formed, and dry etching was performed to form the wiring line. Further, the surface was covered with a silicon nitride film having a film thickness of 200 nm and serving as a protective film of the wiling line surface.

The silicon nitride film on the surface of a pad portion to be connected to the external power supply was removed by dry etching to expose the pad surface. A resist pattern was formed on the back surface of the SOI wafer, that is, on a surface opposite to the surface provided with the piezoelectric element. The size of this pattern was 850 μm×120 μm that was a size larger than the piezoelectric element, and the pattern was produced so that the portion immediately under the piezoelectric element was recessed. Thereafter, silicon was removed up to the silicon oxide film that was a BOX layer (buried oxide film layer) by the Bosch process, and the film upper than the BOX layer served as a membrane.

The predetermined piezoelectric element was obtained as described above.

### Reference Example

A thermally oxidized silicon film for interrupting the continuity between an electric circuit and the silicon film was formed on the SOI wafer surface in a manner akin to that of Example.

In Reference example, to form the insulating film for decreasing a current passing through the piezoelectric film between the piezoelectric film and the upper electrode, the platinum film for controlling the crystal orientation was set to be common to the lower electrode. Therefore, films of 10 mm of titanium and 100 nm of platinum were successively formed on the thermally oxidized silicon film surface by magnetron sputtering.

A lead titanate solution was applied to the platinum surface by spin coating so as to serve as a seed layer in a manner akin to that of Example. Further, a lead zirconate titanate sol-gel liquid was applied by using a spin coater, and annealing was performed so as to form the piezoelectric film.

An insulating film composed of 12 nm of lanthanum aluminate was formed on the piezoelectric film surface by magnetron sputtering. The relative permittivity of the resulting insulating film was 18, and the dielectric breakdown electric field strength was 16.7 MV/cm. Therefore, the product of the relative permittivity and the dielectric breakdown electric field strength was 300.6 MV/cm.

Further, the upper electrode was produced in a manner akin to that of Example.

To form the piezoelectric element, dry etching was performed up to the upper surface of the lower electrode. The steps thereafter were performed in a manner akin to that of Example so as to obtain the piezoelectric element.

### Comparative Example 1

In Example, the insulating film for decreasing a current passing through the piezoelectric film was produced from alumina having a film thickness of 7 nm. The film formation method was an atomic layer deposition method, and trimethylaluminum was used as the raw material. The relative permittivity of alumina was 10, and the dielectric breakdown electric field strength was 13.4 MV/cm. Therefore, the product of the relative permittivity and the dielectric breakdown electric field strength was 134 MV/cm.

### Comparative Example 2

In Example, the insulating film for decreasing a current passing through the piezoelectric film was produced from a silicon nitride film having a film thickness of 8 nm. The film formation method was plasma CVD. The relative permittivity of the silicon nitride film was 12, and the dielectric breakdown electric field strength was 8.8 MV/cm. Therefore, the product of the relative permittivity and the dielectric breakdown electric field strength was 105.6 MV/cm.

The piezoelectric elements described in Example, Reference example, and Comparative examples above were held for 1,000 hours in a constant temperature bath at a temperature of 85° C. and a relative humidity of 85% RH while application of a direct current voltage of 50 V was continued, and the durability was examined. As a result, the piezoelectric elements of Example and Reference example had high durability with no trouble, whereas the piezoelectric elements of Comparative examples did not have predetermined durability.

According to the present disclosure, a piezoelectric element exhibiting a sufficient amount of displacement and having excellent durability, a liquid ejection head including the piezoelectric element, and an image recording apparatus are provided.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-087976 filed May 30, 2022, which is hereby incorporated by reference herein in its entirety.

What is claimed is:

1. A piezoelectric element comprising:
a lower electrode;
a piezoelectric film; and
an upper electrode in this order on a substrate,
wherein an aluminum oxide film containing at least one element selected from the group consisting of elements of group III, elements of group IV, and elements of group V, of the periodic table is disposed between the lower electrode and the piezoelectric film.

2. The piezoelectric element according to claim 1,
wherein a product of a relative permittivity and a dielectric breakdown electric field strength of the aluminum oxide film is more than 134 MV/cm.

3. The piezoelectric element according to claim 1,
wherein the at least one element selected from the group consisting of elements of group III, elements of group IV, and elements of group V, of the periodic table is at least one element selected from the group consisting of titanium, yttrium, hafnium, and lanthanum.

4. The piezoelectric element according to claim 1,
wherein the aluminum oxide is at least one member selected from the group consisting of aluminum titanate, yttrium aluminate, hafnium aluminate, and lanthanum aluminate.

5. The piezoelectric element according to claim 1,
wherein the film thickness of the aluminum oxide film is 13 nm or less.

6. The piezoelectric element according to claim 1,
wherein the aluminum oxide film is disposed between the lower electrode and the piezoelectric film and between the piezoelectric film and the upper electrode.

7. The piezoelectric element according to claim 6,
wherein a total film thickness of the aluminum oxide film disposed between the lower electrode and the piezoelectric film and the aluminum oxide film disposed between the piezoelectric film and the upper electrode is 13 nm or less.

8. A liquid ejection head comprising:
a piezoelectric element which includes a lower electrode, a piezoelectric film, and an upper electrode in this order on a substrate and in which an aluminum oxide film containing at least one element selected from the group consisting of elements of group III, elements of group IV, and elements of group V, of the periodic table is disposed between the lower electrode and the piezoelectric film,
wherein the liquid ejection head is configured to eject a liquid by driving the piezoelectric element.

9. The liquid ejection head according to claim 8,
wherein the liquid is an ink.

10. An image recording apparatus comprising:
a piezoelectric element which includes a lower electrode, a piezoelectric film, and an upper electrode in this order on a substrate and in which an aluminum oxide film containing at least one element selected from the group consisting of elements of group III, elements of group IV, and elements of group V, of the periodic table is disposed between the lower electrode and the piezoelectric film; and
a liquid ejection head configured to eject a liquid by driving the piezoelectric element.
